(19) United States
(12) Patent Application Publication
(10) Pub. No.: US 2025/0205736 A1
(43) Pub. Date: Jun. 26, 2025

(54) PIEZOELECTRIC DEVICE

(71) Applicant: Shanghai Tianma Micro-Electronics Co., Ltd., Shanghai (CN)

(72) Inventors: Kazushige TAKECHI, Kawasaki (JP); Shin TAKEUCHI, Kawasaki (JP); Kenichi HAYASHI, Kawasaki (JP); Hiroshi HAGA, Kawasaki (JP); Kenji SERA, Kawasaki (JP)

(21) Appl. No.: 18/968,649

(22) Filed: Dec. 4, 2024

(30) Foreign Application Priority Data
Dec. 21, 2023 (JP) 2023-216230

(51) Int. Cl. B06B 1/02; B06B 1/06; H10N 30/30

(52) U.S. Cl. CPC B06B 1/0207; B06B 1/0622; H10N 30/302

(57) ABSTRACT

A piezoelectric device has a multilayer structure on a support member and includes a piezoelectric element layer including a piezoelectric element, a thin-film transistor layer located between the piezoelectric element layer and the support member, and a seat disposed between the support member and the thin-film transistor layer. The piezoelectric element includes an upper electrode, a lower electrode, and a piezoelectric film between the upper electrode and the lower electrode. The seat includes a void region inside the seat, the void region overlapping the piezoelectric element in a layering direction.

### CROSS-REFERENCE TO RELATED APPLICATIONS

This non-provisional application claims priority under 35 U.S.C. § 119(a) on Patent Application No. 2023-216230 filed in Japan on Dec. 21, 2023, the entire content of which is hereby incorporated by reference.

### BACKGROUND

This disclosure relates to a piezoelectric device.

Ultrasonic sensors are used in various fields, such as nondestructive object testing, object detection, and fingerprint reading. For example, ultrasonic fingerprint sensors such as integrated micro-electro-mechanical system (MEMS) ultrasonic fingerprint sensors utilizing MEMS technology and thin-film transistor (TFT) ultrasonic sensors have been developed. These fingerprint sensors include a pixel array composed of two-dimensionally arrayed pixels and each pixel includes an ultrasonic transducer.

An example of an ultrasonic transducer is a piezoelectric element. The ultrasonic transducer in a pixel can be composed of one element capable of sending and receiving ultrasound or a pair of a transmitter for sending ultrasound and a receiver for receiving ultrasound. Specifically, the ultrasonic transducer emits ultrasound in response to an electric signal, and also receives ultrasound reflected off an object and converts the received ultrasound into an electric signal.

### SUMMARY

A piezoelectric device has a multilayer structure on a support member and includes a piezoelectric element layer including a piezoelectric element, a thin-film transistor layer located between the piezoelectric element layer and the support member, and a seat disposed between the support member and the thin-film transistor layer. The piezoelectric element includes an upper electrode, a lower electrode, and a piezoelectric film between the upper electrode and the lower electrode. The seat includes a void region inside the seat, the void region overlapping the piezoelectric element in a layering direction.

It is to be understood that both the foregoing general description and the following detailed description are exemplary and explanatory and are not restrictive of this disclosure.

### BRIEF DESCRIPTION OF THE DRAWINGS

FIG. 1 is a block diagram illustrating a configuration of an ultrasonic sensor device in an embodiment.

FIG. 2 illustrates a configuration example of a terminal including an ultrasonic sensor device.

FIG. 3 is a circuit diagram illustrating a circuit configuration of a pixel of a pixel array board in an embodiment.

FIG. 4 schematically illustrates a cross-sectional structure of a part of a pixel.

FIG. 5A is a plan diagram illustrating a partial configuration of a pixel.

FIG. 5B is a plan diagram schematically illustrating a seat of a pixel included in the seat layer shown in FIG. 5A.

FIG. 5C schematically illustrates a layout example of the seat layer and a semiconductor layer located upper than the seat layer in a pixel.

FIG. 5D illustrates the seat layer, the semiconductor layer, and a gate electrode layer located upper than those layers in a pixel.

FIG. 6 provides simulation results on a pixel having the void region described with reference to FIGS. 4 to 5D and a pixel not having a void region.

FIG. 7A is a plan diagram schematically illustrating the structure of a pixel in another embodiment of this specification.

FIG. 7B is a plan diagram illustrating the positional relation among the seat of the seat layer, the void region surrounded by the seat, the central region of the void region, and the lower electrode in the structure illustrated in FIG. 7A.

FIG. 7C schematically illustrates a layout example of the seat layer, the semiconductor layer, and the central region in a pixel.

FIG. 7D schematically illustrates a layout example of the seat layer, the semiconductor layer, the gate electrode layer, and the central region.

FIG. 8 schematically illustrates a cross-sectional structure of a part of one pixel.

FIG. 9A is a plan diagram schematically illustrating a structural example of a pixel including an inorganic substance excluded region.

FIG. 9B is a diagram for illustrating the relations between the seat layer and the other layers or regions in the structural example in FIG. 9A.

FIG. 10 provides simulation results on a pixel having a void region but not having an inorganic substance excluded region as described with reference to FIGS. 7A to 7D and a pixel having a void region and an inorganic substance excluded region as described with reference to FIGS. 8 to 9B.

FIG. 11A illustrates an example of a method of manufacturing a pixel.

FIG. 11B illustrates an example of a method of manufacturing a pixel.

FIG. 11C illustrates an example of a method of manufacturing a pixel.

FIG. 11D illustrates another example of a method of manufacturing a pixel.

FIG. 12A illustrates another example of a method of manufacturing a pixel.

FIG. 12B illustrates another example of a method of manufacturing a pixel.

FIG. 12C illustrates another example of a method of manufacturing a pixel.

FIG. 12D illustrates another example of a method of manufacturing a pixel.

FIG. 13A illustrates still another example of a method of manufacturing a pixel.

FIG. 13B illustrates still another example of a method of manufacturing a pixel.

FIG. 13C illustrates still another example of a method of manufacturing a pixel.

### EMBODIMENTS

Hereinafter, an ultrasonic sensor device of this disclosure will be described in detail with reference to the drawings. The elements in each drawing are changed in size or scale as appropriate to be well recognized in the drawing. The hatches in the drawings are to distinguish the elements and are not to necessarily represent cross-sections. The non-linear elements used as switching elements or amplifying elements are referred to as transistors. The transistors include thin-film transistors (TFTs).

The ultrasonic sensor device of this disclosure is applicable to the fields of medical or industrial testing and fingerprint or object detection. An ultrasonic sensor device in an embodiment of this specification includes a pixel array composed of a plurality of arrayed pixels. The pixel array is composed of pixels disposed in one dimension or two dimensions.

Each pixel includes a piezoelectric element as an ultrasonic transducer. The piezoelectric element sends and receives ultrasound. The piezoelectric element can be composed of one element capable of sending and receiving ultrasound or a pair of a transmitter for sending ultrasound and a receiver for receiving ultrasound. Ultrasound has a frequency higher than 20 kHz, or a frequency above the hearing range. The frequency of the ultrasound is selected appropriately for the field and the situation of use.

The piezoelectric element generates ultrasound in response to an electric signal from a control circuit and converts received ultrasound into an electric signal. The pixel holds the electric signal converted by the piezoelectric element. The signal received and converted by the piezoelectric element is sent from the pixel to the control circuit as a response signal.

A TFT-driven fingerprint sensor including piezoelectric elements has a structure such that a piezoelectric thin film is sandwiched between upper and lower electrodes to utilize its thickness vibration. This configuration has a low voltage-pressure conversion efficiency, which causes a problem of large power consumption when the number of pixels or the area of the sensor is increased. To get a larger amplitude of piezo vibration, a thin-film piezoelectric element utilizing a diaphragm structure has been proposed. As to the fingerprint sensors having the diaphragm structure, however, piezoelectric elements tend to be damaged by the process to form voids.

An embodiment of this disclosure provides the voids under the vibration regions of a thin-film transistor layer to make a diaphragm structure. This configuration reduces the process damage to the piezoelectric elements in forming the voids.

### Device Configuration

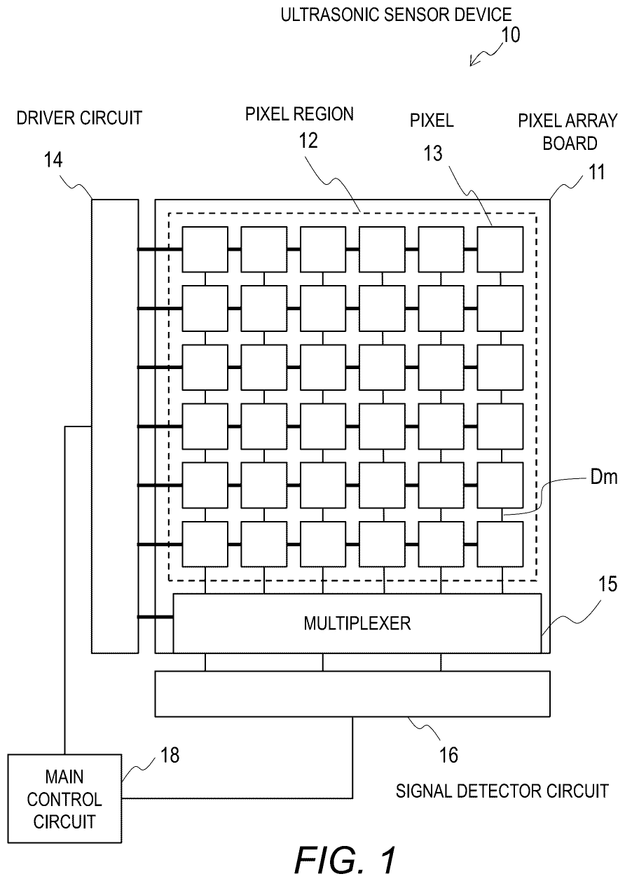

FIG. 1 is a block diagram illustrating a configuration example of an ultrasonic sensor device in an embodiment of this specification. The ultrasonic sensor device 10 includes a pixel array board 11 and control circuits. The ultrasonic sensor device 10 and the pixel array board 11 are piezoelectric element devices. The control circuits include a multiplexer circuit 15, a driver circuit 14, a signal detector circuit 16, and a main control circuit 18. One or more of these circuits can be excluded or another circuit can be added. Moreover, one or more functions of one circuit can be included in another circuit.

The pixel array board 11 includes an insulating substrate (such as a glass substrate) and a pixel region 12 in which pixels 13 are aligned horizontally and vertically like a matrix on the insulating substrate. The pixel array in this example is composed of pixels disposed in two dimensions but the pixel array can be composed of pixels disposed in one dimension.

The multiplexer circuit 15 is fabricated on the insulating substrate of the pixel array board 11 and connected to signal lines Dm for pixel columns disposed vertically in FIG. 1. The multiplexer circuit 15 converts signals from the pixels in time series and outputs the converted signals to a smaller number of signal lines connected to the signal detector circuit 16 for detection.

The driver circuit 14 drives and controls the pixels 13 to send and receive ultrasound. The multiplexer circuit 15 receives an ultrasound detection signal from a pixel 13 transmitted by a signal line Dm and outputs it to the signal detector circuit 16. The signal detector circuit 16 detects signals from individual signal lines converted in time series by the multiplexer circuit 15.

The main control circuit 18 controls the driver circuit 14, the multiplexer circuit 15, and the signal detector circuit 16. The main control circuit 18 acquires and processes response signals output from individual pixels 13. The driver circuit 14, the signal detector circuit 16, and the main control circuit 18 can be mounted on the pixel array board 11 or provided separately from the pixel array board 11 as independent components.

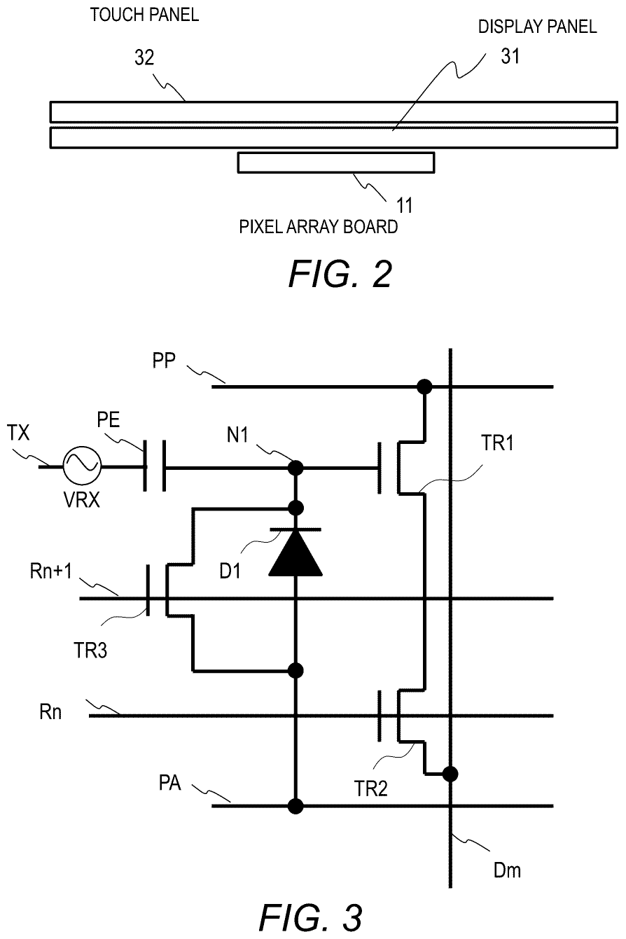

FIG. 2 schematically illustrates a configuration example of a terminal including the pixel array board 11 in an embodiment of this specification. The terminal includes the pixel array board 11, a display panel 31, and a touch panel 32 laid one above another. The touch panel 32 can employ any type of touch detection scheme, such as capacitive type or resistive type. The display panel 31 can be an organic light-emitting diode (OLED) display panel or another type of display panel. The display panel 31 and the touch panel 32 can be controlled by the main control circuit 18 together with the pixel array board 11.

The positional relation among the pixel array board 11, the display panel 31, and the touch panel 32 is not limited to the example of FIG. 2 and can be determined desirably. For example, the pixel array board 11 and the display panel 31 do not overlap and they are disposed to be distant from each other within a plane (when viewed in the layering direction) on the same side or different sides of the touch panel 32. The terminal can include a layered structure of the display panel and a touch panel separately from a layered structure of the pixel array of the ultrasonic sensor device and another touch panel. The pixel array board 11 does not need to be laid on another functional panel such as the display panel or the touch panel.

### Circuit Configuration of Pixel

FIG. 3 illustrates a circuit configuration of a pixel 13. The pixel 13 includes a piezoelectric element PE of an ultrasonic transducer. This piezoelectric element PE has two functions to generate and receive ultrasound. One of the electrodes of the piezoelectric element PE is denoted by a reference sign TX. The electrode TX may be referred to as sending electrode and the other electrode as receiving electrode. In the example of the element configuration described later, the electrode TX is an upper electrode and the other electrode is a lower electrode. The side farther from the insulating substrate is defined as upper side and the side closer from the insulating substrate as lower side.

The piezoelectric element PE induces a voltage VRX in accordance with received ultrasonic vibration. One pixel circuit in the ultrasonic sensor device 10 of this disclosure includes three thin-film transistors TR1, TR2, and TR3, and a diode D1. Examples of the semiconductor material of the thin-film transistors include low-temperature polysilicon, an oxide semiconductor, and amorphous silicon.

The cathode terminal of the diode D1 is connected to a node N1 between the gate terminal of the transistor TR1 and a source/drain terminal of the transistor TR3. The anode terminal is connected to a diode bias line PA. One of the source/drain terminals of the transistor TR1 is connected to a power line PP and the other source/drain terminal is connected to one of the source/drain terminals of the transistor TR2.

The gate terminal of the transistor TR2 is connected to a control line Rn. The other source/drain terminal of the transistor TR2 is connected to a signal line Dm. The gate terminal of the transistor TR3 is connected to a control line Rn+1. The signal transmitted by the control line Rn+1 is the same as the signal transmitted by the control line Rn for the next pixel row. The source/drain terminals of the transistor TR3 are connected to the anode terminal and the cathode terminal of the diode D1.

The transistor TR1 (amplifier transistor) has a function to amplify the potential at one end of the piezoelectric element PE. The transistor TR2 is a switching element and has a function to control the output from the pixel circuit. The transistor TR3 is a switching element and has a function to reset the potentials at the one end of the piezoelectric element PE and the gate electrode of the transistor TR1 (the node N1).

The ultrasonic sensor device 10 in FIG. 1 has one signal line Dm per pixel column consisting of a plurality of vertically aligned pixels 13. All pixels 13 in the same pixel column are connected to one signal line Dm. This signal line Dm is connected to one multiplexer circuit 15 in an end region of the pixel array board 11.

### Structure of Pixel

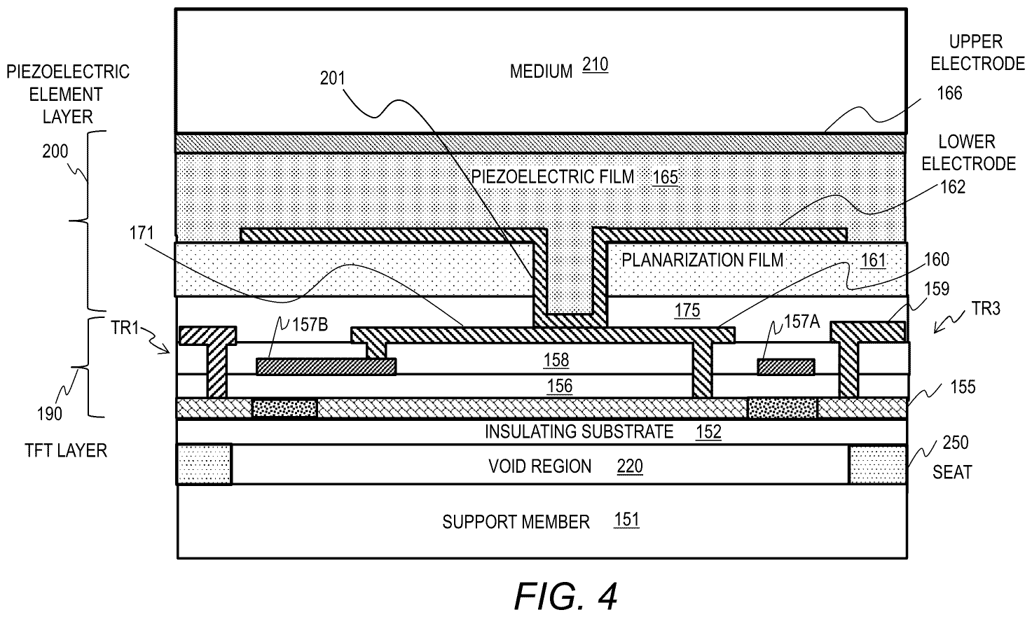

FIG. 4 schematically illustrates a cross-sectional structure of a part of one pixel. The definitions of top and bottom in the following description correspond to the top and the bottom of the drawing. The side closer to the substrate is referred to as lower side and the side farther from substrate as upper side. The pixel array board 11 includes a support member (substrate) 151 and a medium 210 opposed to the support member 151. The medium 210 is a flexible or rigid insulating plate made of resin or glass, for example. A layered structure including a display panel and a touch panel that does not interfere with ultrasound can be provided above or in place of the medium 210 as illustrated in FIG. 2. A plurality of pixels are arrayed between the support member 151 and the medium 210.

The ultrasound generated by a piezoelectric element is reflected off the surface of the medium 210 and returns to the piezoelectric element. If an object such as a human skin is in contact with the surface of the medium 210, the reflection rate of the ultrasound changes. Whether a human skin is present (or ridges and grooves of a human skin) can be sensed with differences in intensity of the reflected ultrasound.

A pixel includes a piezoelectric element layer 200 and a TFT layer 190 between the support member 151 and the medium 210. The TFT layer 190 is located between the piezoelectric element layer 200 and the support member 151. The TFT layer 190 includes pixel circuits for individually driving and controlling piezoelectric elements.

The piezoelectric element layer 200 includes a plurality of piezoelectric elements. A piezoelectric element of an ultrasonic transducer includes a lower electrode 162, an upper electrode 166, and a piezoelectric film (piezoelectric material layer) 165. The piezoelectric film 165 is disposed between the upper electrode 166 and the lower electrode 162. The upper electrode 166 and the lower electrode 162 can be made of a conductor such as ITO or molybdenum. The piezoelectric material can be either organic or inorganic; for example, polyvinylidene fluoride (PVDF) or zirconate titanate (PZT) can be employed.

The upper electrodes 166 of a plurality of pixels in the configuration example of FIG. 4 are different parts of one common electrode. In an embodiment of this disclosure, the upper electrodes 166 of all pixels in the pixel array are different parts of one common electrode having a shape fully covering the entire pixel region. The same applies to the piezoelectric film 165. The lower electrodes 162 are separate among individual pixels. The plurality of lower electrodes 162 are disposed on the top face of a planarization film 161 in the piezoelectric element layer 200. The planarization film 161 can be made of an organic material.

The upper electrodes 166 are sending electrodes and the lower electrodes 162 are receiving electrodes. Supplying an excitation signal to the upper electrodes 166 enables the piezoelectric elements of all pixels to simultaneously generate ultrasound and signals unique to the pixels are received by the lower electrodes 162. The upper electrodes and the piezoelectric film can be separate for individual pixels.

The TFT layer 190 includes pixel circuits for driving and controlling piezoelectric elements. Each pixel circuit includes a plurality of switches. The pixel circuit (TFT layer 190) is fabricated between the support member 151 and the layer of the lower electrode 162. The pixel circuit controls the potential of the lower electrode 162 and further, holds the signal received by the lower electrode 162. The configuration example illustrated in FIG. 4 includes the upper electrode 166 on the side to emit ultrasound and receive reflected ultrasound (the upper side of FIG. 4).

FIG. 4 illustrates transistors TR3 and TR1 in the pixel circuit. The support member 151 is a rigid or flexible plate made of glass or resin, for example. An insulating substrate 152 is provided above the support member 151 and a semiconductor active layer 155 is laid above the insulating substrate 152. The insulating substrate 152 can be made of an organic material such as polyimide or can be a layered structure of an inorganic material such as silicon oxide or silicon nitride and an organic material such as polyimide. The semiconductor active layer 155 includes low-resistive source/drain regions and a highly resistive channel region sandwiched by the source/drain regions. The semiconductor material of the semiconductor active layer 155 can be low-temperature polysilicon, oxide semiconductor, or amorphous silicon.

The semiconductor active layer 155 is covered with a gate insulating layer 156. A gate insulating layer can be made of an inorganic material such as silicon oxide or silicon nitride or can be a layered structure of these materials. For example, the gate insulating layer 156 is made of silicon oxide. Gate electrodes are provided above the semiconductor active layer 155 with the gate insulating layer 156 interposed therebetween. The gate electrodes can be made of a metal such as Ta, Mo, or Al or an alloy of such a metal.

The transistor TR3 includes a gate electrode 157A and the transistor TR1 includes a gate electrode 157B. An interlayer insulating film 158 is provided above the layer including the gate electrodes 157A and 157B. An interlayer insulating film can be made of an inorganic material such as silicon oxide or silicon nitride or can be a layered structure of these materials. For example, the interlayer insulating film 158 is made of silicon nitride.

Within the pixel region 12, a source/drain (S/D) electrode layer is provided above the interlayer insulating film 158 for the transistors. The source/drain electrode layer includes source/drain electrodes 159 and 160 of the transistor TR3 and a line region 171. The source/drain electrode layer can be made of an aluminum-based alloy.

A passivation layer 175 is provided to cover the source/drain electrode layer. A passivation layer can be made of an inorganic material such as silicon oxide or silicon nitride or can be a layered structure of these materials. For example, the passivation layer 175 is made of silicon oxide.

The source/drain electrodes 159 and 160 are connected to the semiconductor active layer 155 through contact regions provided in contact holes opened through the interlayer insulating film 158 and the gate insulating layer 156. The line region 171 extends from the source/drain electrode 160 of the transistor TR3 and connects to the gate electrode 157B of the transistor TR1 via a contact region provided in a contact hole of the interlayer insulating film 158. The line region 171 and the source/drain electrode 160 are included in the same metal layer and they are unseparated.

An insulating planarization film 161 is provided over the source/drain electrodes 159 and 160, and the line region 171. The planarization film 161 can be made of an organic material. A lower electrode 162 is provided above the planarization film 161. The lower electrode 162 is connected to the source/drain electrode 160 or the line region 171 via a contact region 201 provided in a contact hole extending through the planarization film 161 and the passivation layer 175. The TFT layer 190 is fabricated lower than the lower electrode 162.

A piezoelectric film 165 is provided over the lower electrode 162. The piezoelectric film 165 is in contact with the top face of the lower electrode 162 and the top face of the planarization film 161. An upper electrode 166 is provided above and in contact with the piezoelectric film 165. The lower electrode 162, the piezoelectric film 165, and the upper electrode 166 constitute a piezoelectric element.

A seat layer is provided between the insulating substrate 152 and the support member 151. The seat layer includes a plurality of seats 250. Each seat 250 is a seat of the TFT layer 190 of one pixel. The seat layer further includes void regions 220 for individual pixels 13 and each void region 220 overlaps the piezoelectric element of the pixel 13 in the layering direction in at least a part of the region. The seat 250 is located outer than the void region 220.

The void region 220 provides the pixel 13 with a diaphragm structure to get a larger amplitude (sound pressure) of the piezoelectric element and moreover, to reduce the power consumption. The void region 220 is provided opposite to the piezoelectric element layer 200 across the TFT layer 190. For this reason, the process damage to the piezoelectric element can be reduced. In the related arts, the void region and the piezoelectric element layer are provided on the same side with respect to the active element layer (corresponding to the TFT layer in this disclosure) or the void region is adjoining the piezoelectric element layer. In these cases, the piezoelectric element layer tends to receive process damage in producing the void region. An embodiment of this disclosure can solve this problem. The void region 220 also reduces the coupling capacitances between the contact region 201 and the lines in the TFT layer 190 and improves the S/N ratio of the signal from the pixel 13.

In an embodiment of this specification, the entire lower electrode 162 can be included in the void region 220 when viewed in the layering direction (the vertical direction in FIG. 4). This configuration effectively increases the amplitude of the piezoelectric element.

No constituent material of a pixel 13, including the material of the seat 250, exists within the void region 220. The seat 250 and the support member 151 are made of the same or different material. The seat 250 can be made of organic material such as polyimide or photoresist. Employment of organic material facilitates production of a thick seat 250, or a deep void region 220. The depth of the void region 220 means its vertical size; for example, it can be between 20 μm to 500 μm. The seat 250 can be made of inorganic material.

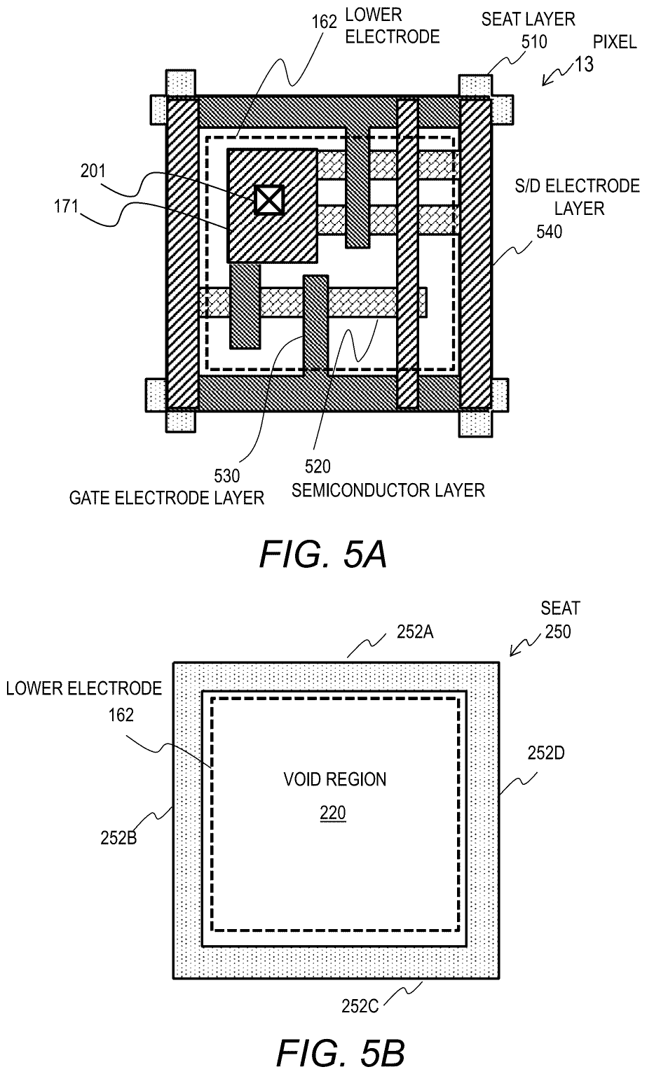

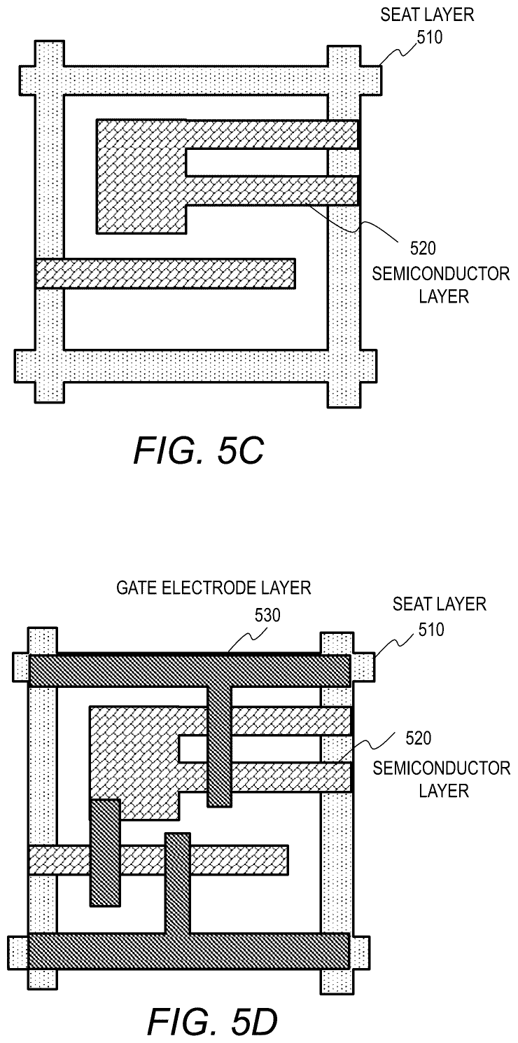

FIG. 5A is a plan diagram illustrating a partial configuration of a pixel 13. As described above, the pixel 13 has a multilayer structure consisting of a plurality of layers. FIG. 5A illustrates some components of some layers of a pixel 13. In FIG. 5A, the outline of the lower electrode 162 of the piezoelectric element is represented by a broken line. The contact region 201 interconnects the lower electrode 162 and the line region 171. The piezoelectric film 165 and the upper electrode 166 are omitted in FIG. 5A.

In FIG. 5A, the components included in the same layer are hatched identically. FIG. 5A illustrates some layers included in the TFT layer 190, specifically, a seat layer 510 including the seat 250, a semiconductor layer 520 including the semiconductor active layer 155 of the TFTs, a gate electrode layer 530 including the gate electrodes 157A and 157B, and an S/D electrode layer 540 including the source/drain electrodes 159 and 160 and the line region 171. The seat layer 510, the semiconductor layer 520, the gate electrode layer 530, and the S/D electrode layer 540 are layered in this order on the support member 151.

FIG. 5B is a plan diagram schematically illustrating the seat 250 of a pixel 13 included in the seat layer 510 shown in FIG. 5A. In the example of FIG. 5B, the seat 250 has a ring-like shape surrounding the entire void region 220. More specifically, the seat 250 has a shape of a square ring and consists of four side regions 252A, 252B, 252C, and 252D. The angles between adjacent side regions are the right angle.

The seat 250 can have a ring-like shape different from the square ring. It can have three, five, or more sides and moreover, the sides can be curved. The seat 250 can have a shape different from a ring. As illustrated in FIG. 5B, the entire lower electrode 162 of one pixel 13 is included in the void region 220 when viewed in the layering direction (the direction perpendicular to the sheet of FIG. 5B). A part of the lower electrode 162 can extend to the outside of the void region 220.

FIG. 5C schematically illustrates a layout example of the seat layer 510 and the semiconductor layer 520 located upper than the seat layer 510 in a pixel 13. FIG. 5D illustrates the seat layer 510, the semiconductor layer 520, and the gate electrode layer 530 located upper than those layers in a pixel 13.

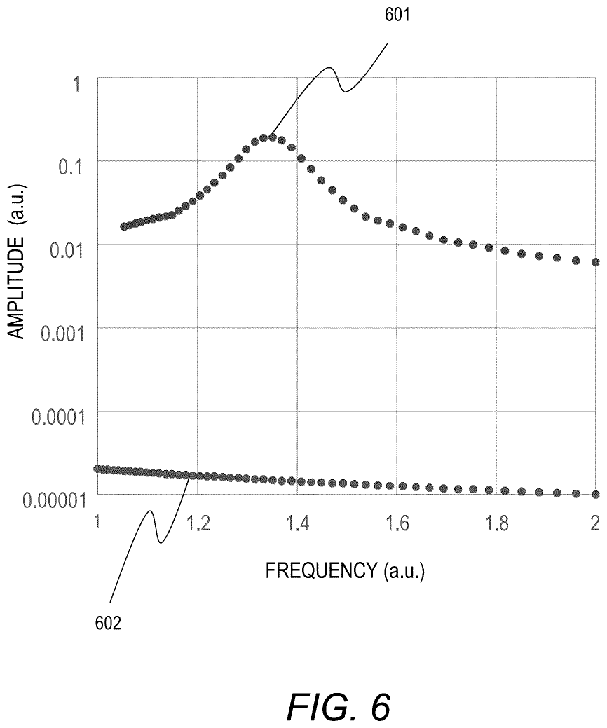

FIG. 6 provides simulation results on a pixel having the void region 220 described with reference to FIGS. 4 to 5D and a pixel not having a void region. The horizontal axis represents vibration frequency of the piezoelectric element and the vertical axis represents amplitude. The curve 601 represents the simulation result on the pixel having a void region 220 and the curve 602 represents the simulation result on the pixel not having a void region 220. As indicated in FIG. 6, the pixel having the void region 220 exhibited larger amplitude to allow lowering the resonance frequency. Low resonance frequency contributes to low power consumption, a high-frequency circuit having a simpler configuration, and small effect of parasitic capacitance.

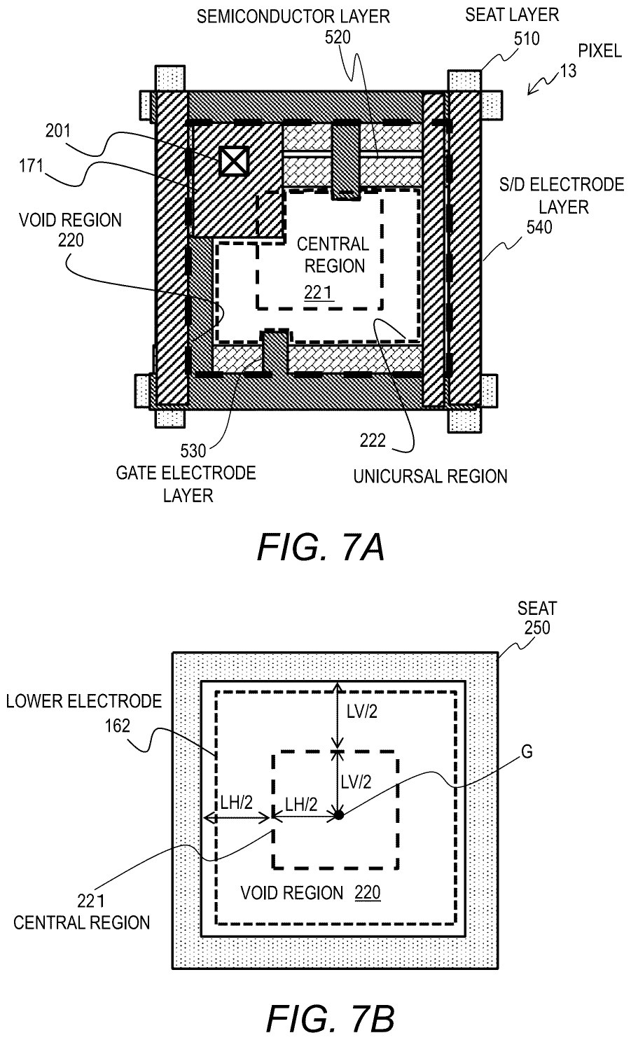

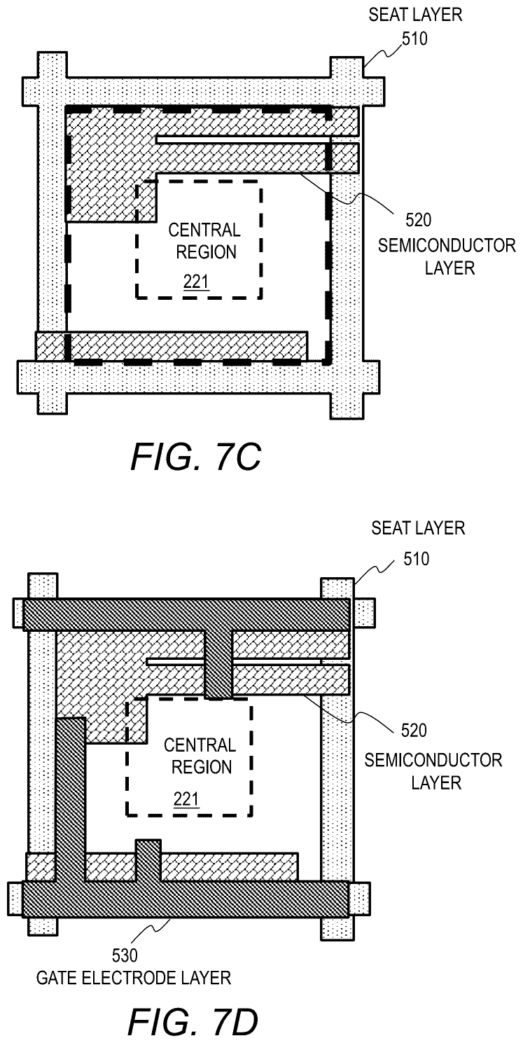

Next, another configuration example of a pixel 13 is described. Unless otherwise specified, the description of the foregoing configuration example is applicable. FIG. 7A is a plan diagram schematically illustrating the structure of a pixel 13 in another embodiment of this specification. Compared to the structural example in FIG. 5A, the semiconductor and the conductors included in the TFT layer 190 are collectively disposed near the ends of the void region 220. In the example in FIG. 7A, components in the semiconductor layer 520, the gate electrode layer 530, and the S/D electrode layer 540 of the TFT layer 190 are disposed collectively near the ends of the region of the pixel 13. The outline of the void region 220 surrounded by the seat 250 is represented by a thick broken line.

There is a unicursal region 222 in the void region 220. The unicursal region 222 is the maximum continuous region in which neither the semiconductor layer nor the electrode layers exist and it is defined by a unicursal line drawn along the ends of the components of the semiconductor layer 520, the gate electrode layer 530, and the S/D electrode layer 540. Since the components of the semiconductor layer 520, the gate electrode layer 530, and the S/D electrode layer 540 are disposed collectively near the ends of the region of the pixel 13, the unicursal region 222 has an area not less than ⅓ of the area of the void region 220. FIG. 7A further indicates a central region 221 including the centroid of the void region 220 by another broken line. The order of layering the layers is the same as the one in the structure illustrated in FIG. 4.

FIG. 7B is a plan diagram illustrating the positional relation among the seat 250 of the seat layer 510, the void region 220 surrounded by the seat 250, the central region 221 of the void region 220, and the lower electrode 162 in the structure illustrated in FIG. 7A. In the example in FIG. 7B, the entire lower electrode 162 is included in the void region 220 and the entire central region 221 is included in the lower electrode 162 when viewed in the layering direction.

In the configuration example in FIG. 7B, the void region 220 surrounded by the ring-like seat 250 consists of the central region 221 including the centroid G of the void region 220 and an outer region outer than the central region 221. The central region 221 has a shape similar to the void region 220 and the centroid G is common to these regions. The outer end of the central region 221 is defined by the midpoints between the centroid G and the outer end of the outer region (the outer end of the void region 220). In the example of FIG. 7B, the void region 220 has a shape of a rectangle having vertical sides having a length of 2LV and horizontal sides having a length of 2LH.

FIG. 7C schematically illustrates a layout example of the seat layer 510, the semiconductor layer 520, and the central region 221 in a pixel 13. FIG. 7D schematically illustrates a layout example of the seat layer 510, the semiconductor layer 520, the gate electrode layer 530, and the central region 221.

With reference to FIG. 7A, the density of conductor and semiconductor regions is lower in the central region 221 than in the outer region. Specifically, the density of conductor regions in the gate electrode layer 530 and the S/D electrode layer 540 is lower in the central region 221 than in the outer region. The density of semiconductor regions in the semiconductor layer 520 is lower in the central region 221 than in the outer region.

This configuration such that the rigid conductor regions and semiconductor regions are disposed collectively near the outer ends leads to acquisition of larger amplitude. Although the central region 221 in the example illustrated in FIGS. 7A to 7D includes some parts of the conductor regions and semiconductor regions, the conductor region and the semiconductor region can be excluded from the central region 221 without any part of them.

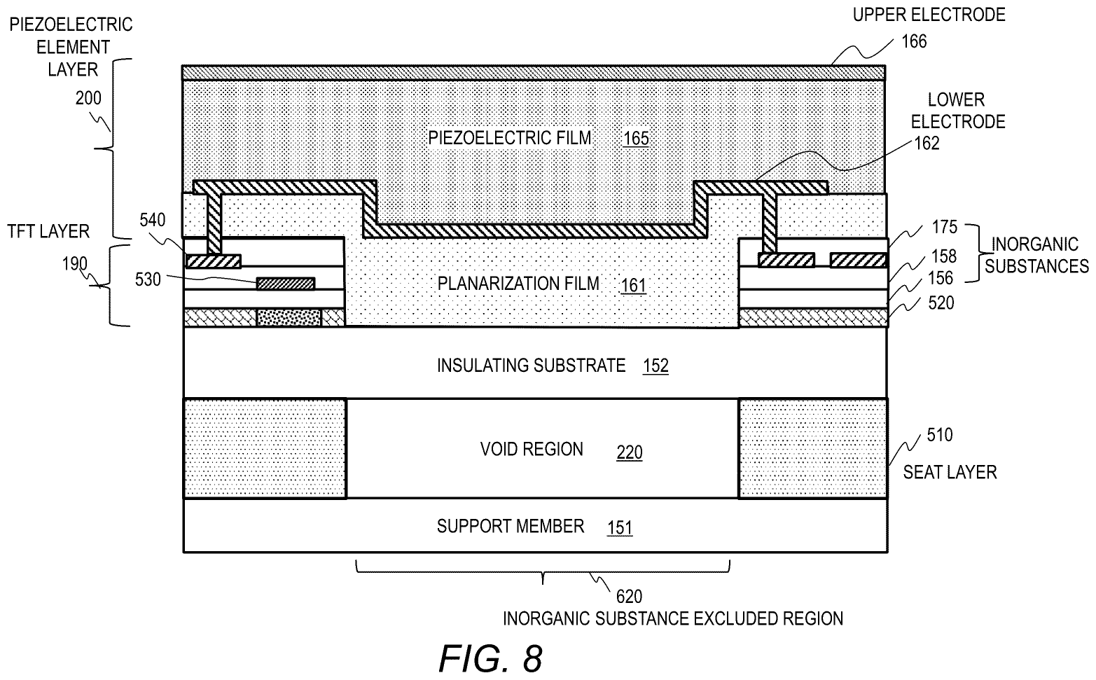

Next, still another configuration example of a pixel 13 is described. FIG. 8 schematically illustrates a cross-sectional structure of a part of one pixel 13. In the following, the description of the foregoing configuration examples is applicable unless otherwise specified. As described above, a void region 220 is provided in the seat layer 510 located above the support member 151. The seat layer 510 is made of photoresist having a thickness of 10 μm to 100 μm, for example.

The insulating substrate 152 is made of an organic substance and located above the seat layer 510. For example, the insulating substrate 152 can be made of polyimide and have a thickness of 1 μm to 10 μm.

The TFT layer 190 includes a plurality of inorganic insulating layers, specifically a gate insulating layer 156, an interlayer insulating film 158, and a passivation layer 175 in this order from the lower side. The gate insulating layer 156 is located between the upper gate electrode layer 530 and the lower semiconductor layer 520. The interlayer insulating film 158 covers the gate electrode layer 530 and it is located between the upper S/D electrode layer 540 and the lower gate electrode layer 530. The passivation layer 175 is located above the S/D electrode layer 540 and the interlayer insulating film 158.

These layers can be made of silicon-based insulators. For example, the gate insulating layer 156 is made of silicon oxide; the interlayer insulating film 158 is made of silicon nitride; and the passivation layer 175 is made of silicon oxide and each inorganic insulating layer can have a thickness of 0.1 μm to 1.0 μm.

In the region of the TFT layer 190 overlapping the void region in the layering direction, inorganic substances are removed from at least a part of the region and do not exist there. Specifically, the gate electrode layer 530 and the S/D electrode layer 540 which function as conductor layers, the semiconductor layer 520, and the gate insulating layer 156, the interlayer insulating film 158, and the passivation layer 175 which function as inorganic insulating layers are removed and they do not exist in the specific region. In the cross-section illustrated in FIG. 8, the conductors, semiconductor, and inorganic insulating materials of the TFT layer 190 have been removed and do not exist in the inorganic substance excluded region 620 that is overlapping the void region 220. That is to say, the inorganic substance excluded region 620 is a unicursal region that is obtained by further removing inorganic insulating materials from the unicursal region 222 illustrated in FIG. 7A.

The region of the TFT layer 190 from which the conductor, semiconductor, and inorganic insulating materials are removed is filled with a part of the planarization film 161. The planarization film 161 is made of an organic insulator such as photoresist or polyimide. The planarization film 161 can have a thickness of 0.5 μm to 2.0 μm, for example. The planarization film 161 is an upper layer of the passivation layer 175 and covers the entire TFT layer 190.

This configuration such that the rigid inorganic materials of the TFT layer 190 are removed from at least a part of the region overlapping the void region 220 improves the amplitude of the piezoelectric element. Inorganic substances of the inorganic insulator, namely conductors or semiconductors, can remain in the inorganic substance excluded region 620.

A piezoelectric element is fabricated above the planarization film 161. The piezoelectric film 165 sandwiched between the upper electrode 166 and the lower electrode 162 can have a thickness of 1 μm to 10 μm, for example. In the structural example in FIG. 8, a part of the lower electrode 162 is located within the void region 220 and the other part is located outside the void region 220 when viewed in the layering direction.

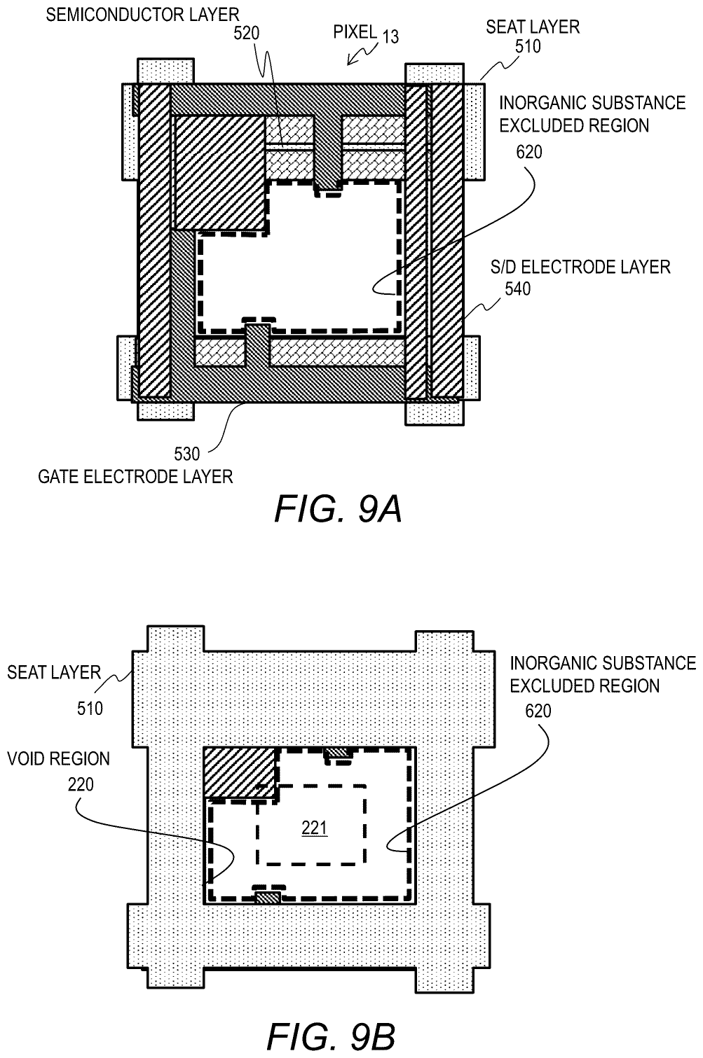

FIG. 9A is a plan diagram schematically illustrating a structural example of a pixel including an inorganic substance excluded region 620. FIG. 9B is a diagram for illustrating the relations between the seat layer 510 and the other layers or regions in the structural example in FIG. 9A. FIG. 9B is a diagram of the structural example in FIG. 9A viewed from the bottom or under the seat layer 510.

The entire inorganic substance excluded region 620 surrounded by a thick broken line overlaps the void region 220 of the seat layer 510. When viewed in the layering direction, the inorganic substance excluded region 620 is a part of the void region 220. A part of the central region 221 is located within the inorganic substance excluded region 620 and the other part is located outside the inorganic substance excluded region 620. The entire central region 221 can be located within the inorganic substance excluded region 620 when viewed in the layering direction.

In the structural example illustrated in FIGS. 9A and 9B, the region overlapping the seat layer 510 is larger than the region located outside the seat layer 510 in each of the semiconductor layer 520, the gate electrode layer 530, and the S/D electrode layer 540. More specifically, the entire semiconductor layer 520 overlaps the seat layer 510 and most of the gate electrode layer 530 and the S/D electrode layer 540 overlap the seat layer 510. Disposing the semiconductor layer 520, the gate electrode layer 530, and the S/D electrode layer 540, namely constituent layers of TFTs, on the seat suppresses the vibration of the TFTs and reduces the electric noise caused by the vibration. The entire gate electrode layer 530 and S/D electrode layer 540 can overlap the seat layer 510 and a part of the semiconductor layer 520 can extend to the outside the seat layer 510.

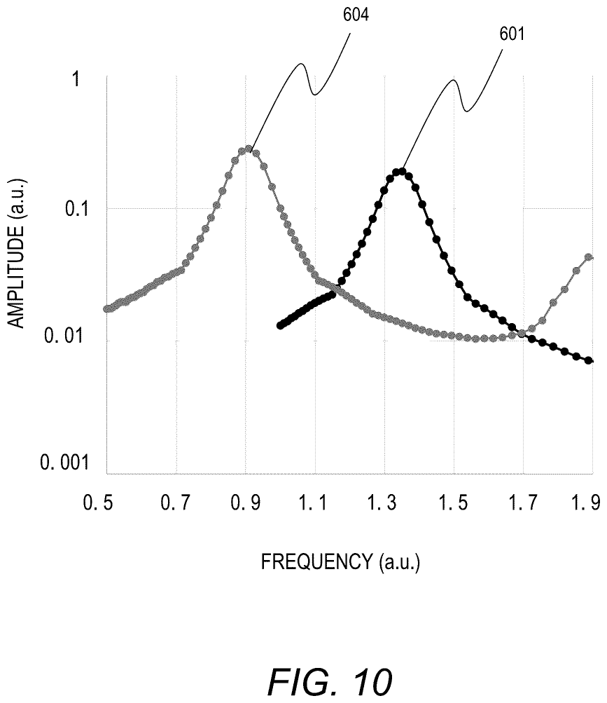

FIG. 10 provides simulation results on a pixel having the void region 220 but not having the inorganic substance excluded region 620 as described with reference to FIGS. 7A to 7D and a pixel having the void region 220 and the inorganic substance excluded region 620 as described with reference to FIGS. 8 to 9B. The horizontal axis represents vibration frequency of the piezoelectric element and the vertical axis represents amplitude.

The curve 601 represents the simulation result on the pixel having the void region 220 but not having the inorganic substance excluded region 620 and the curve 604 represents the simulation result on the pixel having the void region 220 and the inorganic substance excluded region 620. As indicated in FIG. 10, the pixel having the inorganic substance excluded region 620 exhibited larger resonance amplitude to allow lowering the resonance frequency. Low resonance frequency contributes to low power consumption, a high-frequency circuit having a simpler configuration, and small effect of parasitic capacitance.

### Manufacturing Method

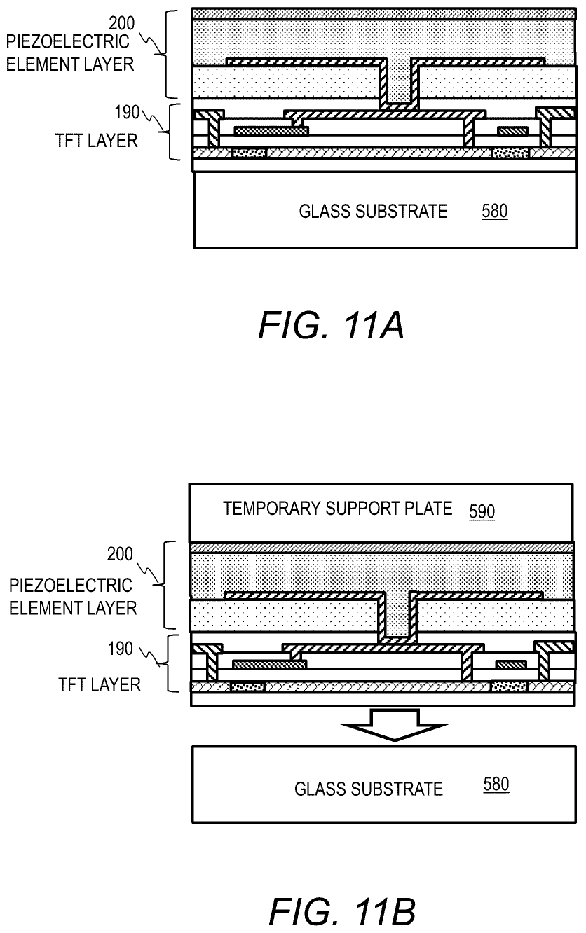

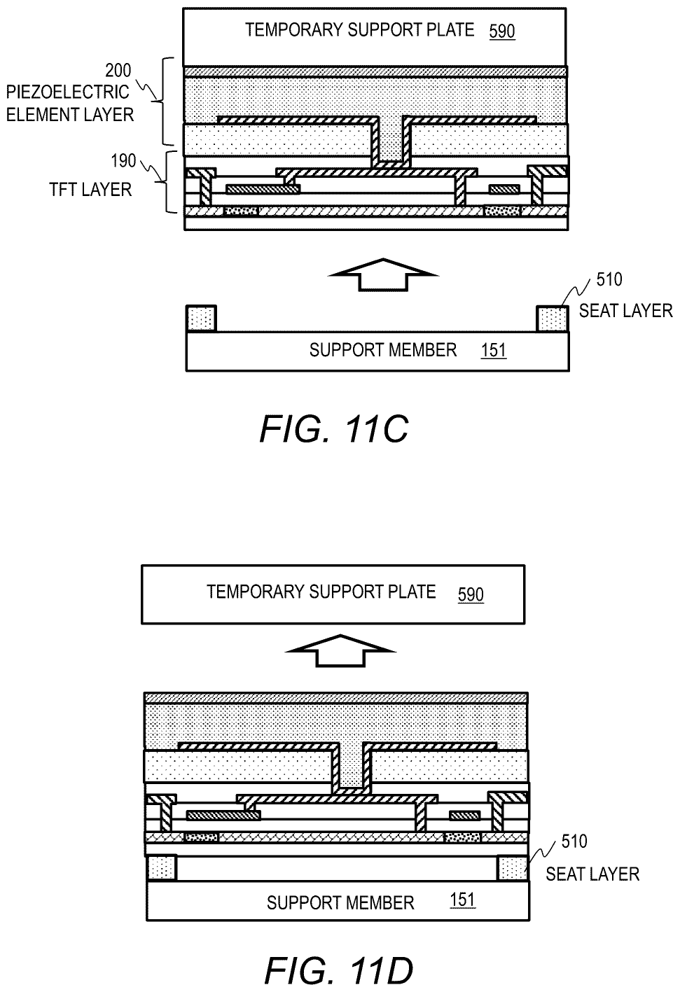

Hereinafter, some methods of manufacturing a pixel 13 on a pixel array board 11 are described. FIGS. 11A to 11D illustrate an example of a method of manufacturing a pixel 13. The method forms patterns of the layers of the TFT layer 190, the piezoelectric element layer 200, and other layers on a glass or polyimide insulating substrate, a glass substrate 580 in this example, by photolithography as illustrated in FIG. 11A.

For example, the metal layers can be deposited by sputtering and the semiconductor layer and the inorganic insulating layers can be deposited by CVD. The organic films can be deposited by spin coating or solution growth technique. Each layer can be patterned by providing a photoresist pattern, etching the layer, and removing the photoresist pattern. A low-resistive region of a semiconductor layer can be formed by impurity ion implantation using a gate electrode as a mask or plasma treatment on oxide semiconductor.

Next, as illustrated in FIG. 11B, the method bonds a temporary support plate 590, which can be made of glass, to the work in process on the opposite side of the glass substrate 580 and detaches the glass substrate 580 from the TFT layer 190. The glass substrate 580 can be detached by laser lifting-off, for example.

Next, as illustrated in FIG. 11C, the method forms a seat layer 510 on a support member 151 by photoresist patterning and bonds the top face of the seat layer 510 and the undersurface of the TFT layer 190 together after heating, for example. Another method forms the seat layer 510 on the undersurface of the TFT layer 190 by photoresist patterning and bonds a support member 151 onto the undersurface of the seat layer 510.

Next, as illustrated in FIG. 11D, the method detaches the temporary support plate 590 from the piezoelectric element layer 200. The temporary support plate 590 can be detached by laser lifting-off, for example. Another example uses an adhesive that reduces its adhesive power by heat in bonding the temporary support plate 590 in FIG. 11B. Then, the temporary support plate 590 is detached simultaneously when the TFT-layer 190 is heated to be bonded to the seat layer in FIG. 11C.

As described above, an embodiment of this disclosure detaches the substrate after fabricating a TFT layer and a piezoelectric element layer on the substrate, forms a seat on an insulating substrate or the TFT layer, and bonds the seat to the insulating substrate or the TFT layer.

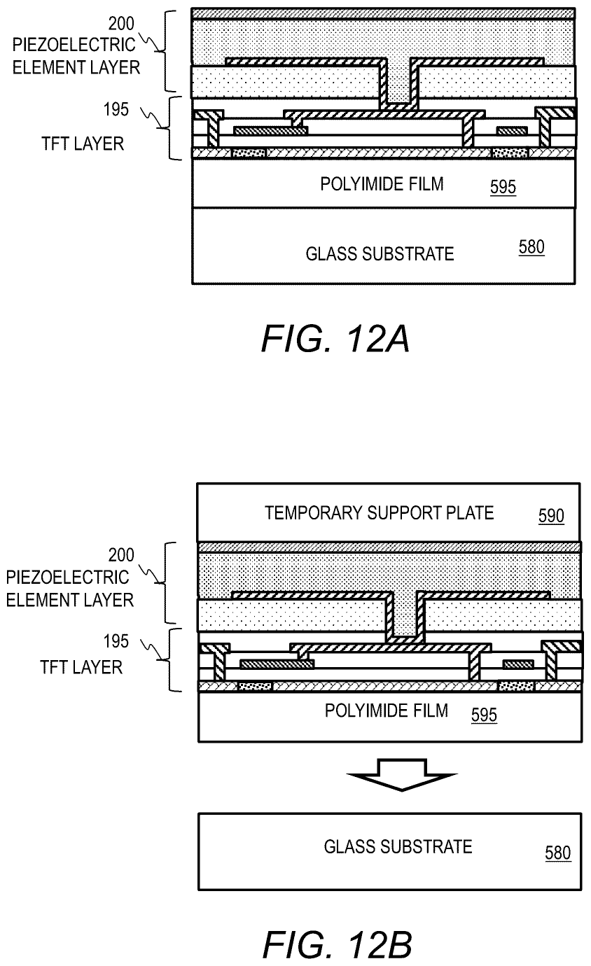

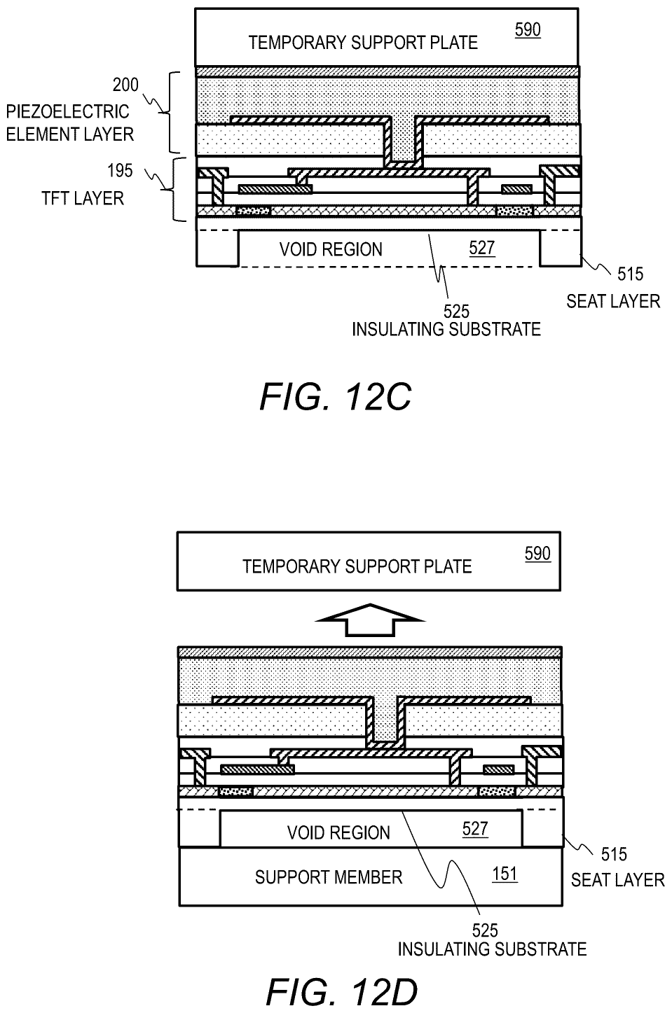

FIGS. 12A to 12D illustrate another example of a method of manufacturing a pixel 13. As illustrated in FIG. 12A, this method deposits a polyimide film 595 on an insulating substrate, the glass substrate 580 in this example, by solution-growth technique or vapor deposition. Thereafter, the method fabricates a TFT layer 195 and a piezoelectric element layer 200. This example does not include an insulating substrate 152 under the semiconductor layer of the TFT layer 195.

Next, as illustrated in FIG. 12B, the method bonds a temporary support plate 590 to the top face of the piezoelectric element layer 200 and detaches the glass substrate 580 by laser lifting-off, for example. Next, as illustrated in FIG. 12C, the method partially removes the polyimide film 595 by patterning to form a seat layer 515 and an insulating substrate 525. As noted from this description, the seat layer 515 (the seat thereof) and the insulating substrate 525 are parts of the same polyimide film 595 and they are integrally made of the same material. Avoid region 527 is produced in the removed region. In this example, the seat layer 515 is located on the undersurface of the insulating substrate 525 or opposite to the TFT layer 195 across the insulating substrate 525.

As illustrated in FIG. 12D, the method detaches the temporary support plate 590 from the piezoelectric element layer 200 and places the work in process on a support member 151. The temporary support plate 590 can be detached by laser lifting-off, for example. As described above, an embodiment of this disclosure deposits an insulating film (for example, a polyimide film) on a substrate and fabricates a TFT layer and a piezoelectric element layer on the insulating film. Thereafter, the method detaches the substrate and removes a part of the insulating film to produce a seat, a void region, and an insulating substrate. This method enables efficient manufacture.

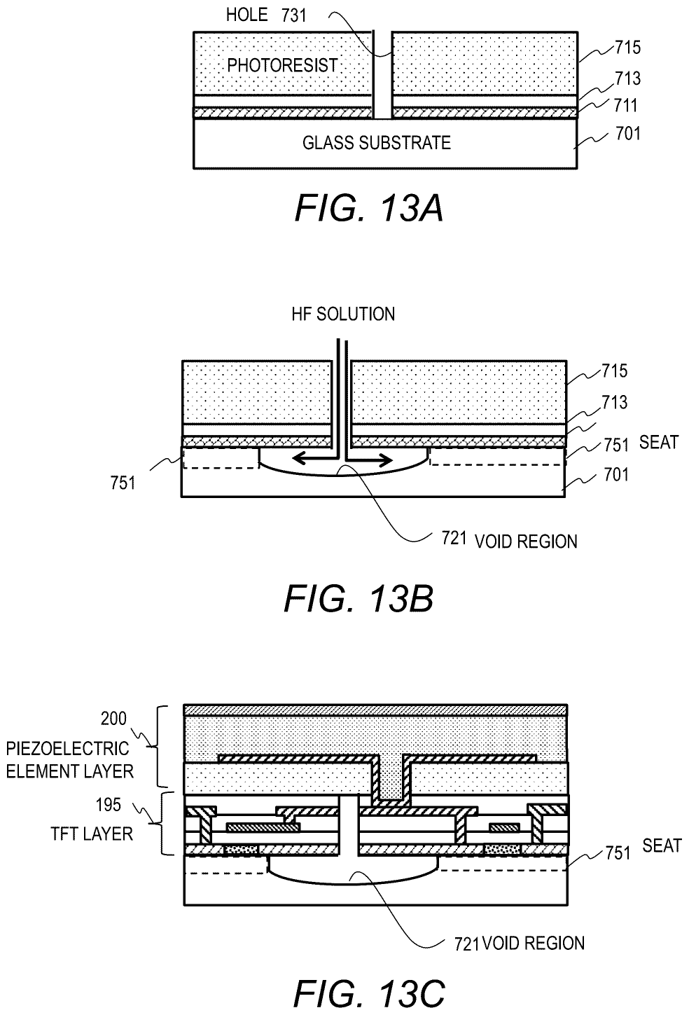

FIGS. 13A to 13C illustrate still another example of a method of manufacturing a pixel 13. This example produces a void and a seat on a glass substrate by etching with hydrofluoric acid (HF). This method enables efficient manufacture.

As illustrated in FIG. 13A, the method deposits a semiconductor film 711, an insulating film 713 to become a gate insulating layer, and a photoresist film 715 in this order on a glass substrate 701. Thereafter, the method opens a hole in the photoresist film 715 by photolithography and further, forms a hole 731 passing through the photoresist film 715, the insulating film 713, and the semiconductor film 711 by etching. The insulating film 713 is optional and an inorganic or organic insulating film can be provided between the semiconductor film 711 and the glass substrate 701.

Next, as illustrated in FIG. 13B, the method etches the glass substrate 701 with an HF solution as an etchant through the hole 731 to produce a void region 721. One or more holes 731 can be opened to produce one void region 721. In the glass substrate 701, the region surrounding the void region 721 is a seat 751 (seat region) and the other region is a region of a support member. In this example, the region under the seat 751 and the void region 721 corresponds to a support member. That is to say, the seat 751 and the support member are integrally made of the same material. After producing the void region 721, the method removes the photoresist film 715.

Next, as illustrated in FIG. 13C, the method fabricates a TFT layer 195 and a piezoelectric element layer 200. For example, the method deposits a gate electrode layer by sputtering and patterns it by photolithography (including etching). Subsequently, the method produces a low-resistive region by impurity ion implantation using the gate electrode as a mask or plasma treatment. Thereafter, the method deposits an interlayer insulating film by CVD and opens holes in the interlayer insulating film and the gate insulating layer by photolithography. The method deposits an S/D electrode layer by sputtering and patterns it by photolithography.

Next, the method deposits a passivation layer by CVD, for example, deposits a planarization film by coating and opens holes by patterning. The method deposits a layer for a lower electrode of the piezoelectric element by sputtering and patterns it by photolithography. The method deposits a piezoelectric film by coating or vapor deposition and moreover, an upper electrode by sputtering, for example. Through the foregoing processes, the TFT layer 195 and the piezoelectric layer 200 are fabricated. The hole extending through the TFT layer 195 in FIG. 13C can be filled with the material of the planarization film.

As described above, an embodiment of this disclosure produces the semiconductor film 711 on the glass substrate 701 and thereafter, produces a void region in the glass substrate with an etchant poured into a hole opened through the semiconductor film 711. The manufacturing method further fabricates the TFT layer 195 including the semiconductor film 711 and the piezoelectric element layer 200 thereabove by photolithography. This method can produce the void region and the seat efficiently.

As set forth above, embodiments of this disclosure have been described; however, this disclosure is not limited to the foregoing embodiments. Those skilled in the art can easily modify, add, or convert each element in the foregoing embodiments within the scope of this disclosure. A part of the configuration of one embodiment can be replaced with a configuration of another embodiment or a configuration of an embodiment can be incorporated into a configuration of another embodiment.

What is claimed is:

1. A piezoelectric device having a multilayer structure on a support member, the piezoelectric device comprising:
a piezoelectric element layer including a piezoelectric element;
a thin-film transistor layer located between the piezoelectric element layer and the support member; and
a seat disposed between the support member and the thin-film transistor layer,
wherein the piezoelectric element includes an upper electrode, a lower electrode, and a piezoelectric film between the upper electrode and the lower electrode, and
wherein the seat includes a void region inside the seat, the void region overlapping the piezoelectric element in a layering direction.

2. The piezoelectric device according to claim 1, wherein the entire lower electrode is included in the void region when viewed in the layering direction.

3. The piezoelectric device according to claim 1,
wherein the seat is made of material different from material of the support member, and
wherein the seat has a ring-like shape surrounding the entire void region.

4. The piezoelectric device according to claim 1, wherein a substrate made of the same material as the seat and integrally with the seat is located between the seat and the thin-film transistor layer.

5. The piezoelectric device according to claim 1, wherein semiconductors and conductors included in the thin-film transistor layer are disposed collectively near ends of the void region.

6. The piezoelectric device according to claim 1,
wherein a region of the thin-film transistor layer overlapping the void region consists of a central region including the centroid of the void region and an outer region outer than the central region,
wherein outer ends of the central region are defined by midpoints between the centroid and outer ends of the outer region, and
wherein density of conductor regions and semiconductor regions is lower in the central region than in the outer region.

7. The piezoelectric device according to claim 1,
wherein the thin-film transistor layer includes a semiconductor layer, a gate electrode layer, and a source/drain electrode layer, and
wherein a maximum continuous region defined by unicursal lines drawn along ends of components of the semiconductor layer, the gate electrode layer, and the source/drain electrode layer and not including any part of the semiconductor layer, the gate electrode layer, and the source/drain electrode layer has an area not less than ⅓ of the area of the void region.

8. The piezoelectric device according to claim 1,
wherein the thin-film transistor layer includes one or more inorganic substance layers, and
wherein inorganic substances in the thin-film transistor layer are removed from at least a part of a region overlapping the void region in the layering direction and the part of the region is filled with an organic substance.

9. The piezoelectric device according to claim 1, wherein the support member and the seat are integrally made of the same material.

10. The piezoelectric device according to claim 1,
wherein the piezoelectric element layer includes a plurality of piezoelectric elements laid out in a plane,
wherein the seat has a plurality of void regions each overlapping a piezoelectric element in the layering direction between the thin-film transistor layer and the support member, and
wherein the seat surrounds each of the plurality of void regions separately between the thin-film transistor layer and the support member.
